(19) United States
(12) Patent Application Publication
(10) Pub. No.: US 2026/0118459 A1
(43) Pub. Date: Apr. 30, 2026

(54) METHOD, SYSTEM, PROCESSING CIRCUITRY, AND COMPUTER PROGRAM PRODUCT FOR ADJUSTING AN MRI CENTER FREQUENCY

(71) Applicant: CANON MEDICAL SYSTEMS CORPORATION, Otawara-shi (JP)

(72) Inventor: Andrew James WHEATON, Vernon Hills, IL (US)

(73) Assignee: CANON MEDICAL SYSTEMS CORPORATION, Otawara-shi (JP)

(21) Appl. No.: 18/925,608

(22) Filed: Oct. 24, 2024

(51) Int. Cl. G01R 33/48; G01R 33/56

(52) U.S. Cl. CPC G01R 33/4828; G01R 33/56

(57) ABSTRACT

A method, system and computer program product for controlling a Magnetic Resonance Imaging (MRI) apparatus such that a center frequency used to obtain MRI image data is corrected based on plural chemical models (e.g., using known relative locations of fat versus water in plural spectra).

### BACKGROUND OF THE INVENTION

### Field of the Invention

This disclosure relates to a method, system, processing circuitry, and computer program product for controlling a Magnetic Resonance Imaging (MRI) apparatus is described herein, and, in one embodiment, to a method, system, processing circuitry, and computer program product for controlling a center frequency used to obtain MRI image data.

### Discussion of the Background

In known MRI systems, clinical MR scanner typically undergo a prescan process in which the center frequency (CF) for the particular subject to be scanned is calibrated. Each patient distorts the B0 field uniquely, so the CF must be calibrated for each patient and for each RF coil. Calibrations also may be specific to the anatomy to be scanned. Incorrect CF calibration may result in loss of image quality (IQ) due to reduced water signal, poor fat suppression, and/or geometric inaccuracies.

As part of the MRI process, different chemical species (e.g., water, aliphatic fat, olefinic fat, silicone) have different characteristic resonant frequencies due to their chemical structures, and the frequency separation between species is known a priori based on physical chemistry models and lab experiments. Typically, an MR scanner aims to select the water frequency as the CF as most MR imaging is focused on water in the tissue.

In one known CF calibration approach, the CF is simply assigned to the frequency with the peak signal in the prescan spectrum. However, such an approach can incorrectly identify the CF if there is more fat than water in the anatomy-specific prescan area scanned which can occur in fatty tissues.

Another known approach to CF calibration applies a model fit in which a model kernel of the ideal peaks is built. The kernel can include fat and water (or fat, water, and silicone) built at their predetermined chemical separations. In one such configuration, the kernel is convolved with a measured spectrum obtained with a fat suppression mode using inversion recovery (often referred to as STIR mode) turned off (STIR_{off}) by shifting it in frequency steps and calculating the cross-correlation value. The shift corresponding to the highest cross-correlation value is chosen as the value of the adjustment to be applied to CF. As shown in FIG. 1A, the above model-based approach can accurately predict CF even when certain types of noisy data are present because the model utilizes the overall shape of the predicted spectrum. Alternatively, as shown in FIG. 1B, when the fat signal is significantly higher than the water signal, the process can fail because the cross-correlation may be inadvertently highest when the predicted CF is actually in the fat region.

As used herein, STIRₒₙ means that a short tau inversion recovery RF pulse is applied to the sample. By leveraging the difference in longitudinal relaxation times between fat and water (fat is shorter), the inversion recovery time (TI) is selected such that fat signal is mostly suppressed while the water signal is mostly intact. In the STIR_{off} case, the inversion recovery RF pulse is absent. Therefore, in the STIR_{off} data, both the fat and water signals are unsuppressed.

Another known approach used by in known MRI systems of Applicant (described in U.S. Pat. No. 9,662,037) utilizes information from two acquired spectra—one acquired STIR turned off (STIR_{off}) and one acquired with fat suppression using inversion recovery turned on (STIRₒₙ). An estimate of the water frequency is then determined in each spectrum by determining frequencies F0ₒₙ and F0_{off}, respectively, which are the peak signals S1ₒₙ and S1_{off}, respectively, in the STIRₒₙ and STIR_{off} spectra, respectively. The process generally then analyzes the spectra −3 to −4 ppm downfield from the initial estimates (F0ₒₙ and F0_{off}) to determine the peak signals (S2ₒₙ and S2_{off}) in those regions based on the fact that the chemical shift of fat is −3.5 ppm relative to the location of water in the spectrum. Accordingly, the peak signals are ideally located at: S2on @ F0ₒₙ−3.5 ppm and S2off @ F0_{off}−3.5 ppm. The process then uses the values of S1ₒₙ, S1_{off}, S2_{off}, and S2ₒₙ to facilitate determining a corrected value for CF. For example, when the fat signal is properly suppressed in the STIRₒₙ spectrum as expected, the CF is confirmed to be F0ₒₙ because (S2off/S2on)>(S1off/S1on).

However, by utilizing the peak signals in regions of the spectra estimated to correspond to water and fat, the process may incorrectly predict the center frequency. For example, as shown in FIG. 1C, the process may detect a peak near the edge of a broad water peak as the center frequency when in actuality the center frequency is more appropriately predicted at the center of that broad peak. As shown in FIG. 1D, the process may incorrectly predict the center frequency as the fat frequency (left peak) instead of the water frequency (right peak) in the presence of a large fat signal.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1A is a schematic illustration of a model-based cross-correlation process for determining water frequency to be used as a center frequency;

FIG. 1B is a schematic illustration of a model-based cross-correlation process that misidentifies the water frequency in the presence of a peak signal resulting from fatty tissue;

FIG. 1C is a schematic illustration of an algorithmic process that misidentifies the water frequency (to be used as a center frequency) in light of an early peak in a noisy spectrum having a broad water peak;

FIG. 1D is a schematic illustration of an algorithmic process that misidentifies the water frequency (to be used as a center frequency) in light of a high fat peak relative to the water peak;

FIG. 2 is a schematic of an MRI apparatus;

FIG. 3 is a flowchart showing a generalized process of correcting a center frequency as described herein; and

FIG. 4 is a pseudocode-based implementation of a process of determining a center frequency correction;

FIG. 5A is a tabular representation of exemplary two kernels for use with spectra obtained with different suppression statuses; and

FIG. 5B is a graphical representation of the exemplary two kernels of FIG. 5A for use with spectra obtained with different suppression statuses.

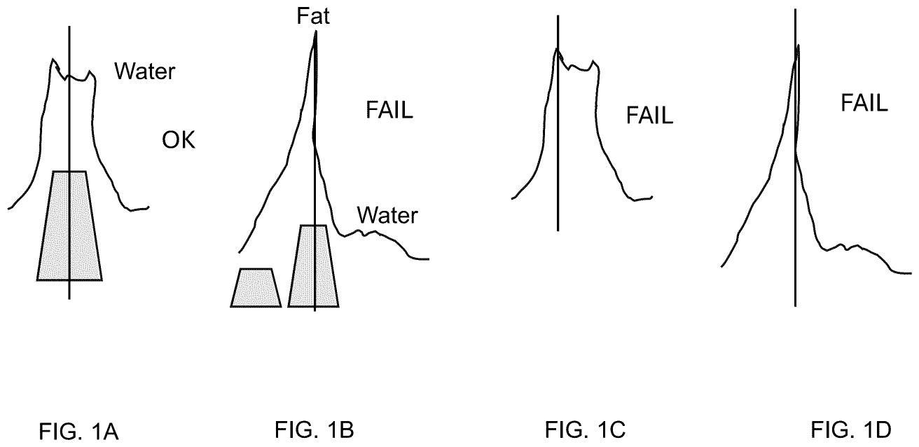

### DETAILED DESCRIPTION

The terms “a” or “an”, as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language). Reference throughout this document to “one embodiment”, “certain embodiments”, “an embodiment”, “an implementation”, “an example” or similar terms means that a particular feature, structure, or characteristic described in connection with the embodiment is included in at least one embodiment of the present disclosure. Thus, the appearances of such phrases or in various places throughout this specification are not necessarily all referring to the same embodiment. Furthermore, the particular features, structures, or characteristics may be combined in any suitable manner in one or more embodiments without limitation.

The present disclosure is related to a method, system, and non-transitory computer-readable storage medium storing computer-readable instructions for correcting a center frequency used by an MRI system when obtaining MRI images by applying models jointly to plural spectra that were acquired in first and second sequence conditions with different suppression conditions.

In one embodiment, it can be appreciated that the present disclosure can be viewed as a system. While the present exemplary embodiments will refer to an MRI apparatus, it can be appreciated that other system configurations can use other medical imaging apparatuses (e.g., CT systems and combined MRI/CT systems).

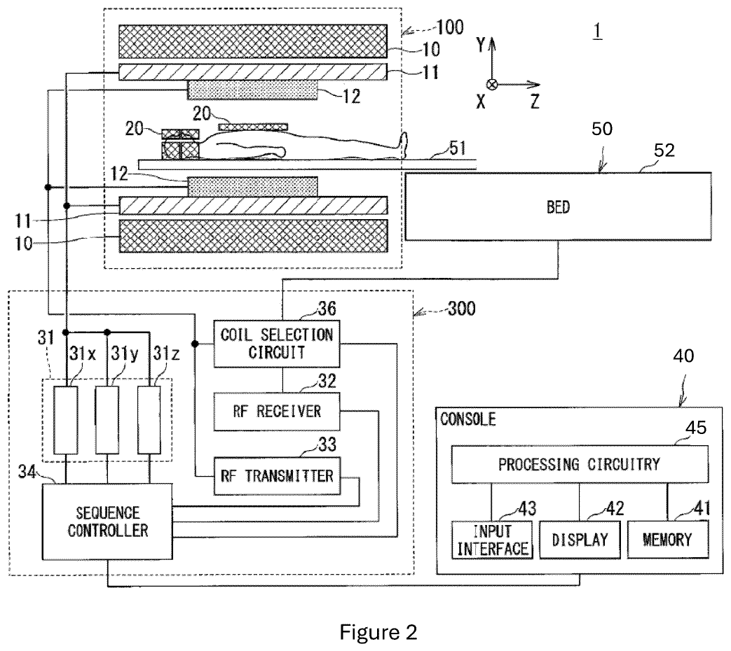

Referring now to the drawings, FIG. 2 is a block diagram illustrating overall configuration of an MRI apparatus 1. The MRI apparatus 1 includes a gantry 100, a control cabinet 300, a console 40, a bed 50, and radio frequency (RF) coils 20. The gantry 100, the control cabinet 300, and the bed 50 constitute a scanner, i.e., an imaging unit.

The gantry 100 includes a static magnetic field magnet 10, a gradient coil 11, and a whole body (WB) coil 12, and these components are housed in a cylindrical housing. The bed 50 includes a bed body 52 and a table 51.

The control cabinet 300 includes three gradient coil power supplies 31 (31 x for an X-axis, 31 y for a Y-axis, and 31 z for a Z-axis), a coil selection circuit 36, an RF receiver 32, an RF transmitter 33, and a sequence controller 34.

The console 40 includes processing circuitry 45, a memory 41, a display 42, and an input interface 43. The console 40 functions as a host computer.

The static magnetic field magnet 10 of the gantry 100 is substantially in the form of a cylinder and generates a static magnetic field inside a bore into which an object such as a patient is transported. The bore is a space inside the cylindrical structure of the gantry 100. The static magnetic field magnet 10 includes a superconducting coil inside, and the superconducting coil is cooled down to an extremely low temperature by liquid helium. The static magnetic field magnet 10 generates a static magnetic field by supplying the superconducting coil with an electric current provided from a static magnetic field power supply (not shown) in an excitation mode. Afterward, the static magnetic field magnet 10 shifts to a permanent current mode, and the static magnetic field power supply is separated. Once it enters the permanent current mode, the static magnetic field magnet 10 continues to generate a strong static magnetic field for a long time, for example, over one year.

The gradient coil 11 is also substantially in the form of a cylinder and is fixed to the inside of the static magnetic field magnet 10. This gradient coil 11 applies gradient magnetic fields (for example, gradient pulses) to the object in the respective directions of the X-axis, the Y-axis, and the Z-axis, by using electric currents supplied from the gradient coil power supplies 31 x, 31 y, and 31 z.

The bed body 52 of the bed 50 can move the table 51 in the vertical direction and in the horizontal direction. The bed body 52 moves the table 51 with an object placed thereon to a predetermined height before imaging. Afterward, when the object is imaged, the bed body 52 moves the table 51 in the horizontal direction so as to move the object to the inside of the bore.

The WB body coil 12 is shaped substantially in the form of a cylinder so as to surround the object and is fixed to the inside of the gradient coil 11. The WB coil 12 applies RF pulses transmitted from the RF transmitter 33 to the object. Further, the WB coil 12 receives magnetic resonance signals, i.e., MR signals emitted from the object due to excitation of hydrogen nuclei.

The MRI apparatus 1 may include the RF coils 20 as shown in FIG. 2 in addition to the WB coil 12. Each of the RF coils 20 is a coil placed close to the body surface of the object. There are various types for the RF coils 20. For example, as the types of the RF coils 20, as shown in FIG. 2, there are a body coil attached to the chest, abdomen, or legs of the object and a spine coil attached to the back side of the object. As another type of the RF coils 20, for example, there is a head coil for imaging the head of the object. Although most of the RF coils 20 are coils dedicated for reception, some of the RF coils 20 such as the head coil are a type that performs both transmission and reception. The RF coils 20 are configured to be attachable to and detachable from the table 51 via a cable.

The RF transmitter 33 generates each RF pulse on the basis of an instruction from the sequence controller 34. The generated RF pulse is transmitted to the WB coil 12 and applied to the object. An MR signal is generated from the object by the application of one or plural RF pulses. Each MR signal is received by the RF coils 20 or the WB coil 12.

The MR signals received by the RF coils 20 are transmitted to the coil selection circuit 36 via cables provided on the table 51 and the bed body 52. The MR signals received by the WB coil 12 are also transmitted to the coil selection circuit 36.

The coil selection circuit 36 selects MR signals outputted from each RF coil 20 or MR signals outputted from the WB coil depending on a control signal outputted from the sequence controller 34 or the console 40.

The selected MR signals are outputted to the RF receiver 32. The RF receiver 32 performs analog to digital (AD) conversion on the MR signals, and outputs the converted signals to the sequence controller 34. The digitized MR signals are referred to as raw data in some cases. The AD conversion may be performed inside each RF coil 20 or inside the coil selection circuit 36.

The sequence controller 34 performs a scan of the object by driving the gradient coil power supplies 31, the RF transmitter 33, and the RF receiver 32 under the control of the console 40. When the sequence controller 34 receives raw data from the RF receiver 32 by performing the scan, the sequence controller 34 transmits the received raw data to the console 40.

The sequence controller 34 includes processing circuitry (not shown). This processing circuitry is configured as, for example, a processor for executing predetermined programs or configured as hardware such as a field programmable gate array (FPGA) or an application specific integrated circuit (ASIC).

The console 40 includes the memory 41, the display 42, the input interface 43, and the processing circuitry 45 as described above.

The memory 41 is a recording medium including a read-only memory (ROM) and a random access memory (RAM) in addition to an external memory device such as a hard disk drive (HDD) and an optical disc device. The memory 41 stores various programs executed by a processor of the processing circuitry 45 as well as various types of data and information.

The input interface 43 includes various devices for an operator to input various types of information and data, and is configured of a mouse, a keyboard, a trackball, and/or a touch panel, for example.

The display 42 is a display device such as a liquid crystal display panel, a plasma display panel, and an organic EL panel.

The processing circuitry 45 is a circuit equipped with a central processing unit (CPU) and/or a special-purpose or general-purpose processor, for example. The processor implements various functions described below by executing the programs stored in the memory 41. The processing circuitry 45 may be configured as hardware such as an FPGA and an ASIC. The various functions described below can also be implemented by such hardware. Additionally, the processing circuitry 45 can implement the various functions by combining hardware processing and software processing based on its processor and programs.

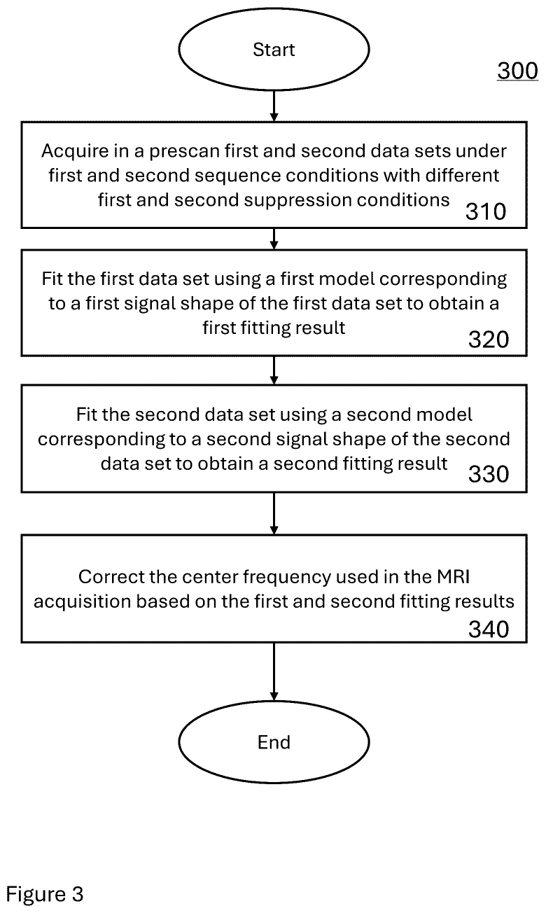

FIG. 3 is a flowchart showing a generalized process as described herein. In method 300, the process begins in step 310 by acquiring in a prescan first and second data sets under first and second sequence conditions with different first and second suppression conditions (e.g., STIRₒₙ vs. STIR_{off}). In step 320, the first data set is fit using a first model corresponding to a first signal shape of the first data set to obtain a first fitting result. In step 330, the second data set is fit using a second model corresponding to a second signal shape of the second data set to obtain a second fitting result. In steps 320 and 330, the frequency shift applied to the models is the same in both datasets (STIRₒₙ and STIR_{off}). In step 340, the center frequency used in the MRI acquisition (i.e., after the prescan) is corrected based on the first and second fitting results. The center frequency adjusting method 300 then ends and the system can begin the MRI acquisition process using the corrected center frequency.

More specifically, in step 310, the STIRₒₙ and STIR_{off} spectra are acquired with an original estimate of the center frequency F0_{original}. Fast Fourier Transforms (FFTs) are then applied to the spectra and the absolute value of the results are obtained so as to create magnitude spectra. Each spectrum is then normalized separately so that they can be matched to model kernels of commensurate magnitudes.

In steps 320 and 330, the two model kernels (kernelₒₙ and kernel_{off}) are shifted (compared to F0_{original}) relative to their corresponding magnitude spectra STIRₒₙ and STIR_{off}. A dot product is calculated at each point i for each shifted kernel×spectrum such that:

a(i)=kernelₒₙ(i+shift)×STIRₒₙ(i); and

b(i)=kernel_{off}(i+shift)×STIR_{off}(i).

The summed value at each point ((sign)a²(i) and (sign)b²(i)) is then squared, and a polarity is assigned at point i based on shifted kernel polarity at that point (‘signed L2 norm’).

In step 340, each convolved data set is summed for all points i (A−Σa; B−Σb), and the sums are combined with weighting factor k₁ and k₂ such that the weighted sum Q is given by:

Q=k₁A+k₂B.

The shift value that produces the highest value of Q corresponds to the frequency correction factor ΔF, and CF=F0_{original}+ΔF.

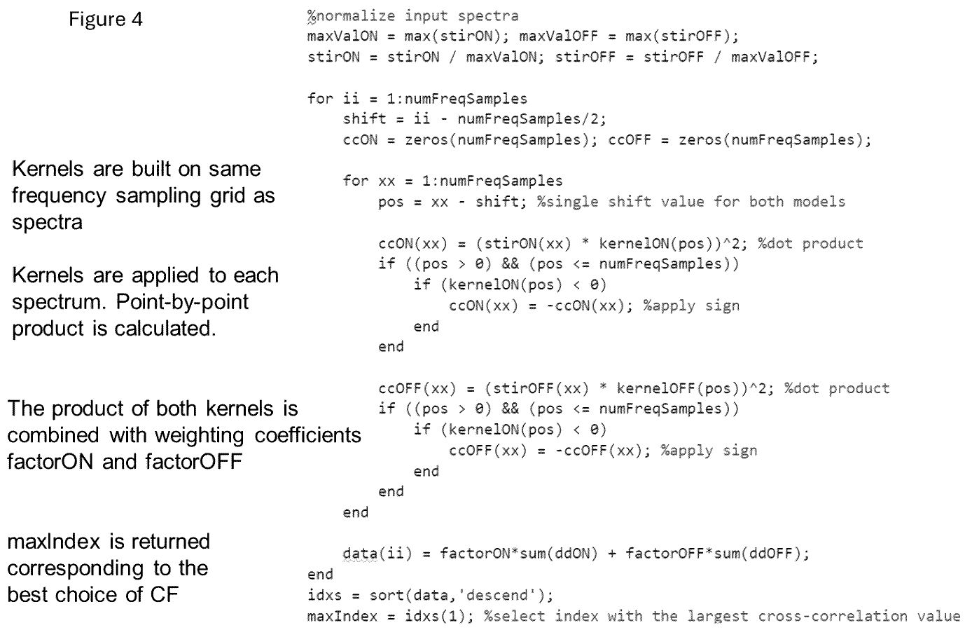

FIG. 4 is a pseudocode implementation of a process of determining a center frequency correction. As shown therein, the spectra are stored in arrays stirON and stirOFF, which are normalized using their respective highest values maxValON and maxValOFF. The process then shifts the data in increments and calculates dot products ccOn and ccOFF are calculated at each shift using the normalized spectra (stirON and stirOFF) and the corresponding kernels (kernelON and kernelOFF). The weighted sum is calculated for each shift and added to the weighted sum array data at position ii (corresponding to the current shift). By sorting the values in the array data, the process finds the shift corresponding to the highest weighted sum and uses that shift as a correction factor for the original center (F0_{original}).

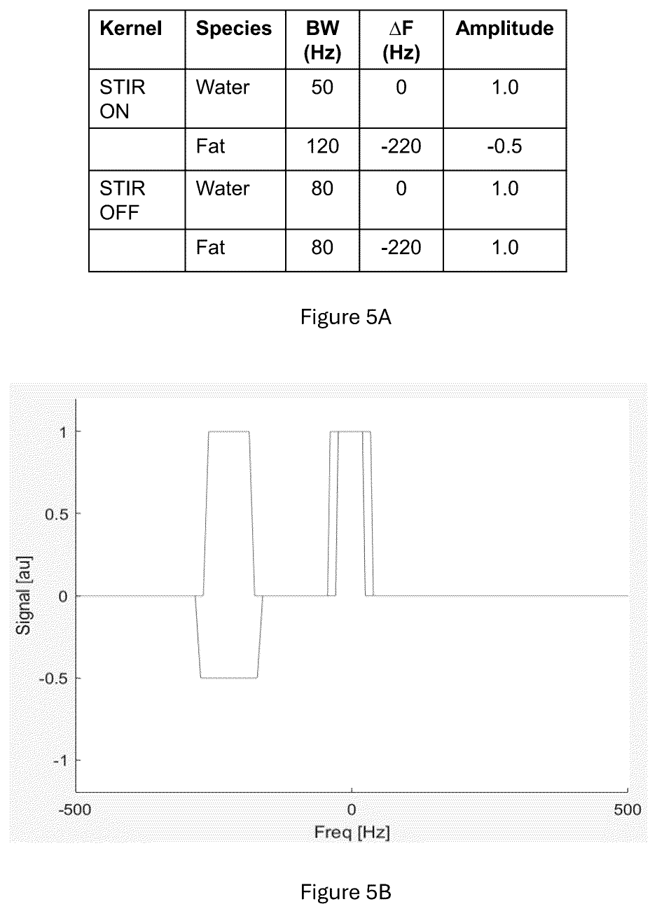

In one embodiment, the kernels are generated to facilitate finding a single peak. FIG. 5A is a tabular representation of exemplary two kernels for use with spectra obtained with different suppression statuses (e.g., STIRₒₙ and STIR_{off}). FIG. 5B is a graphical representation of the exemplary two kernels of FIG. 5A for use with spectra obtained with different suppression statuses. Both representations indicate that the kernels are designed to accentuate the distinction between water and fat which are separated by a known frequency. In the illustrated embodiments, a first model utilizes a first model kernel shaped to a first shape corresponding to predicted relative signal locations of at least two chemical species under the first suppression status of the first sequence conditions by having the kernel for STIRₒₙ utilize a negative amplitude centered about a frequency indicative of fat. This negative fat amplitude discourages mistakenly assigning F0 to a fat peak. The STIR_{OFF} kernel is configured to find fat and water together by using a second model including a second model kernel shaped to a second shape corresponding to predicted relative signal locations of the at least two chemical species under the second suppression status of the second sequence conditions. It has the same amplitude for fat and water to discourage weighting the solution toward incorrectly assigning CF to a strong fat peak. It has similar bandwidths (BWs) to protect against broad fat or water peaks. When generating a weighted sum, weighting of the STIR_{off} data more than the STIRₒₙ data helps in the water peak detection. For example, k₁=1 and k₂=2 have been determined empirically to help in the water peak detection.

Alternatively, other forms of weighting functions are possible. For example ((sign)a²(i) and (sign)b²(i)) could be used or ((sign)a^{N}(i) and (sign)b^{N}(i)) could be used where N is any number not equal to zero.

In general, the STIR_{off} kernel should have positive water amplitude and positive fat amplitude as it is intended to find two peaks (fat and water). However, the STIRₒₙ kernel should have a positive water amplitude and a negative fat amplitude in order to help encourage it to find a single peak. The negative fat amplitude acts as a penalty term to penalize fat. This encourages the total value to find water.

The above methods combine the advantages of the model fit approach with physics information provided by STIRon vs STIRoff. In a test set of 40 volunteer samples (head, pelvis, c-spine, t-spine, shoulder, knee, wrist), the dual kernel-based models worked in 40/40 cases whereas Applicant's previous algorithm worked in 39/40 cases.

Rather than using STIRon and STIRoff as mechanisms to accentuate the difference between fat and water, other possible species identification mechanisms include at least the following three techniques. First, a saturation recovery pulse ON/OFF can be used instead of an inversion recovery pulse ON/OFF. The fat will recovery more quickly than water, leading to a suppression of water. Second, a long duration between the excitation pulse and readout (referred to as “time to echo” or “TE”) can be used versus a short TE. The T2 of fat is known to be shorter than water. So a long TE dataset will have suppressed fat and stronger water signal. The short TE dataset will have stronger fat and stronger water signal. Third, the TE time can be selected to be in-phase/out-of-phase based on frequency evolution of the chemical species. In the in-phase data (e.g. TE=2.2 ms at 3 T), where water and fat signal are additive, the fat peak will be strong. In the out-of-phase TE (e.g. 3.4 ms at 3 T), the fat and water signals partially cancel each other leading to a partial suppression of the fat peak.

The methods and systems described herein can be implemented in a number of technologies but generally relate to imaging devices and processing circuitry for performing the processes described herein. In one embodiment, the processing circuitry (e.g., image processing circuitry and controller circuitry) is implemented as one of or as a combination of: an application specific integrated circuit (ASIC), a field programmable gate array (FPGA), a generic array of logic (GAL), a programmable array of logic (PAL), circuitry for allowing one-time programmability of logic gates (e.g., using fuses) or reprogrammable logic gates. Furthermore, the processing circuitry can include a computer processor and having embedded and/or external non-volatile computer readable memory (e.g., RAM, SRAM, FRAM, PROM, EPROM, and/or EEPROM) that stores computer instructions (binary executable instructions and/or interpreted computer instructions) for controlling the computer processor to perform the processes described herein. The computer processor circuitry may implement a single processor or multiprocessors, each supporting a single thread or multiple threads and each having a single core or multiple cores.

Embodiments of the present disclosure may also be as set forth in the following parentheticals.
(1) A method for correcting a center frequency of a magnetic resonance imaging apparatus, including, but not limited to: acquiring (a) a first data set acquired under first sequence conditions in which at least one chemical species is suppressed according to a first suppression status and (b) a second data set acquired under second sequence conditions, wherein at least one chemical species is suppressed differently under the first suppression status of the first sequence than under the second suppression status of the second sequence; fitting the first data set using a first model corresponding to a first signal shape of the first data set to obtain a first fitting result; fitting the second data set using a second model corresponding to a second signal shape of the second data set to obtain a second fitting result using a same frequency shift value when fitting the first and second data sets; and correcting the center frequency based on the first and second fitting results.
(2) The method according to (1), wherein the first model comprises a first model kernel shaped to a first shape corresponding to predicted relative signal locations of at least two chemical species under the first suppression status of the first sequence conditions.
(3) The method according to (2), wherein the second model comprises a second model kernel shaped to a second shape corresponding to predicted relative signal locations of the at least two chemical species under the second suppression status of the second sequence conditions.
(4) The method according to any one of (1)-(3), wherein fitting the first data set using the first model corresponding to the first signal shape of the first data set to obtain the first fitting result comprises convolving the first data set with the first model to obtain a series of first fitting results.
(5) The method according to (4), wherein fitting the second data set using the second model corresponding to the second signal shape of the second data set to obtain the second fitting result comprises convolving the second data set with the second model to obtain a series of second fitting results.
(6) The method according to (5), wherein correcting the center frequency based on the first and second fitting results includes, but is not limited to: obtaining weighted sums for the first and second series of fitting results; and correcting the center frequency to correspond to a frequency having a greatest weight sum of the obtained weighted sums for the first and second series of fitting results.
(7) The method according to (6), wherein obtaining weighted sums for the first and second series of fitting results includes, but is not limited to, using a greater weighting for fitting results of the first and second fitting results that correspond to a model of the first and second models having a higher suppression status.
(8) The method according to any one of (1)-(7), wherein the first and second suppression statuses are STIRon and STIRoff.
(9) The method according to any one of (1)-(7), wherein the first and second suppression statuses are saturation recovery pulse “on” and saturation recovery pulse “off.”
(10) The method according to any one of (1)-(7), wherein the first and second suppression statuses are long TE and short TE.
(11) The method according to any one of (1)-(7), wherein the first and second suppression statuses are in-phase TE time and out-of-phase TE time.
(12) The method according to any one of (3)-(7), wherein the first and second model kernels include at least two model species with a same polarity of amplitudes.
(13) The method according to any one of (3)-(7), wherein the first and second model kernels include at least two model species with different polarity of amplitudes.
(14) An apparatus for correcting a center frequency of a magnetic resonance imaging apparatus, including, but not limited to: processing circuitry configured to perform the steps of any one of (1)-(13).
(15) A non-transitory computer-readable storage medium storing computer-readable instructions that, when executed by a computer, cause the computer to perform an image processing method of any one of (1)-(13).

Thus, the foregoing discussion discloses and describes merely exemplary embodiments of the present disclosure. As will be understood by those skilled in the art, the present disclosure may be embodied in other specific forms without departing from the spirit thereof. Accordingly, the disclosure of the present disclosure is intended to be illustrative, but not limiting, of the scope of the disclosure, as well as other claims. The disclosure, including any readily discernible variants of the teachings herein, defines, in part, the scope of the foregoing claim terminology such that no inventive subject matter is dedicated to the public.

1. A method for correcting a center frequency of a magnetic resonance imaging apparatus, the method comprising:
acquiring (a) a first data set acquired under first sequence conditions in which at least one chemical species is suppressed according to a first suppression status and (b) a second data set acquired under second sequence conditions, wherein at least one chemical species is suppressed differently under the first suppression status of the first sequence than under the second suppression status of the second sequence;
fitting the first data set using a first model corresponding to a first signal shape of the first data set to obtain a first fitting result;
fitting the second data set using a second model corresponding to a second signal shape of the second data set to obtain a second fitting result using a same frequency shift value when fitting the first and second data sets; and
correcting the center frequency based on the first and second fitting results.

2. The method as claimed in claim 1, wherein the first model comprises a first model kernel shaped to a first shape corresponding to predicted relative signal locations of at least two chemical species under the first suppression status of the first sequence conditions.

3. The method as claimed in claim 2, wherein the second model comprises a second model kernel shaped to a second shape corresponding to predicted relative signal locations of the at least two chemical species under the second suppression status of the second sequence conditions.

4. The method as claimed in claim 1, wherein fitting the first data set using the first model corresponding to the first signal shape of the first data set to obtain the first fitting result comprises convolving the first data set with the first model to obtain a series of first fitting results.

5. The method as claimed in claim 4, wherein fitting the second data set using the second model corresponding to the second signal shape of the second data set to obtain the second fitting result comprises convolving the second data set with the second model to obtain a series of second fitting results.

6. The method as claimed in claim 5, wherein correcting the center frequency based on the first and second fitting results comprises:
obtaining weighted sums for the first and second series of fitting results; and
correcting the center frequency to correspond to a frequency having a greatest weight sum of the obtained weighted sums for the first and second series of fitting results.

7. The method as claimed in claim 6, wherein obtaining weighted sums for the first and second series of fitting results comprises using a greater weighting for fitting results of the first and second fitting results that correspond to a model of the first and second models having a higher suppression status.

8. The method as claimed in claim 1, wherein the first and second suppression statuses are STIRₒₙ and STIR_{off}.

9. The method as claimed in claim 1, wherein the first and second suppression statuses are saturation recovery pulse “on” and saturation recovery pulse “off.”

10. The method as claimed in claim 1, wherein the first and second suppression statuses are long TE and short TE.

11. The method as claimed in claim 1, wherein the first and second suppression statuses are in-phase TE time and out-of-phase TE time.

12. The method as claimed in claim 3, wherein the first and second model kernels include at least two model species with a same polarity of amplitudes.

13. The method as claimed in claim 3, wherein the first and second model kernels include at least two model species with different polarity of amplitudes.

14. An apparatus for performing image processing, comprising:
processing circuitry configured to:
acquire (a) a first data set acquired under first sequence conditions in which at least one chemical species is suppressed according to a first suppression status and (b) a second data set acquired under second sequence conditions, wherein at least one chemical species is suppressed differently under the first suppression status of the first sequence than under the second suppression status of the second sequence;
fit the first data set using a first model corresponding to a first signal shape of the first data set to obtain a first fitting result;
fit the second data set using a second model corresponding to a second signal shape of the second data set to obtain a second fitting result using a same frequency shift value when fitting the first and second data sets; and
correct the center frequency based on the first and second fitting results.

15. The apparatus as claimed in claim 14, wherein the first model comprises a first model kernel shaped to a first shape corresponding to predicted relative signal locations of at least two chemical species under the first suppression status of the first sequence conditions.

16. The apparatus as claimed in claim 15, wherein the second model comprises a second model kernel shaped to a second shape corresponding to predicted relative signal locations of the at least two chemical species under the second suppression status of the second sequence conditions.

17. The apparatus as claimed in claim 14, wherein the first and second suppression statuses are STIRₒₙ and STIR_{off}.

18. The apparatus as claimed in claim 14, wherein the first and second suppression statuses are saturation recovery pulse “on” and saturation recovery pulse “off.”

19. The apparatus as claimed in claim 14, wherein the first and second suppression statuses are long TE and short TE.

20. The apparatus as claimed in claim 14, wherein the first and second suppression statuses are in-phase TE time and out-of-phase TE time.
